(19) United States
(12) Patent Application Publication
(10) Pub. No.: US 2005/0066248 A1
(43) Pub. Date: Mar. 24, 2005

(54) Methods and systems for determining memory requirements for device testing

(76) Inventor: Reid Hayhow, LaPorte, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/666,024

(22) Filed: Sep. 18, 2003

(51) Int. Cl. G06F 11/00; G01R 31/28

(52) U.S. Cl. 714/738

(57) ABSTRACT

Methods and systems for determining memory requirements for device testing are disclosed. In one embodiment, the method comprises reading a test file including a plurality of test vectors to be applied to a device, and determining a required memory needed to execute the plurality of test vectors.

### BACKGROUND OF THE INVENTION

Prior to shipping a device, such as a system-on-a-chip (SOC), the device must be tested to determine whether it has been manufactured correctly and is fully operational. A variety of testers are available for such testing. Typically, a tester is a very large and expensive machine which is designed to precisely position the placement of logic signal transitions at very high speeds. Most testers are aimed at creating a “functional environment” for a device which mimics the environment in which the device will eventually be used, to thereby demonstrate that the device will behave as expected in that environment.

For functional tests, a tester applies a series of “test vectors” to the inputs of the device. A test vector is a critically timed cycle of events lasting a short period of time referred to as a “vector cycle”. Within a vector cycle, and at precisely calculated times, logic signal drivers in the tester apply stimulus to device inputs. At the same or some precisely delayed time, logic signal comparators in the tester monitor responses at device outputs. When many test vectors are executed sequentially, discrepancies between monitored and expected device outputs, if any, are noted as device failures.

An alternative or adjunct to functional testing is “structural” testing. Sometimes called “scan” testing, structural testing enables the testing of structures which are deeply embedded within a device. Rather than testing the device's internal structure by applying stimulus to the device's inputs, structural testing involves shifting a series of test vectors into the core of a device, and after each test vector is shifted in, launching the test vector and capturing a response. Each response is then shifted out of the device. In this manner, a tester can verify that all of a device's elements are present and operational. An assumption of structural testing is that if all elements are present and operational, then the elements will contribute to performing the greater and intended functions of the device (e.g., adding, shifting, etc.), and the device will function as designed.

Each type of test (functional, structural, or other types of tests) may have different memory requirements for the tester to execute the test vectors for each test to be performed. The requirements may also vary between different tests of each type. If the tester does not have sufficient allocated memory, one or more tests may fail.

### SUMMARY OF THE INVENTION

Methods and systems for determining memory requirements for device testing are disclosed. In one embodiment, the method comprises reading a test file including a plurality of test vectors to be applied to a device. A required memory needed to execute the plurality of test vectors is determined.

### BRIEF DESCRIPTION OF THE DRAWINGS

Illustrative embodiments of the invention are illustrated in the drawings in which:

FIG. 1 illustrates an exemplary plan view of a system which may be used to determine a required memory needed for device testing;

FIG. 2 illustrates an exemplary method that may be used by the system of FIG. 1 to determine memory requirements needed for device testing; and

FIG. 3 illustrates an exemplary method for determining memory needed to execute test vectors for each pin of a tester that may be used by the method of FIG. 2.

### DETAILED DESCRIPTION

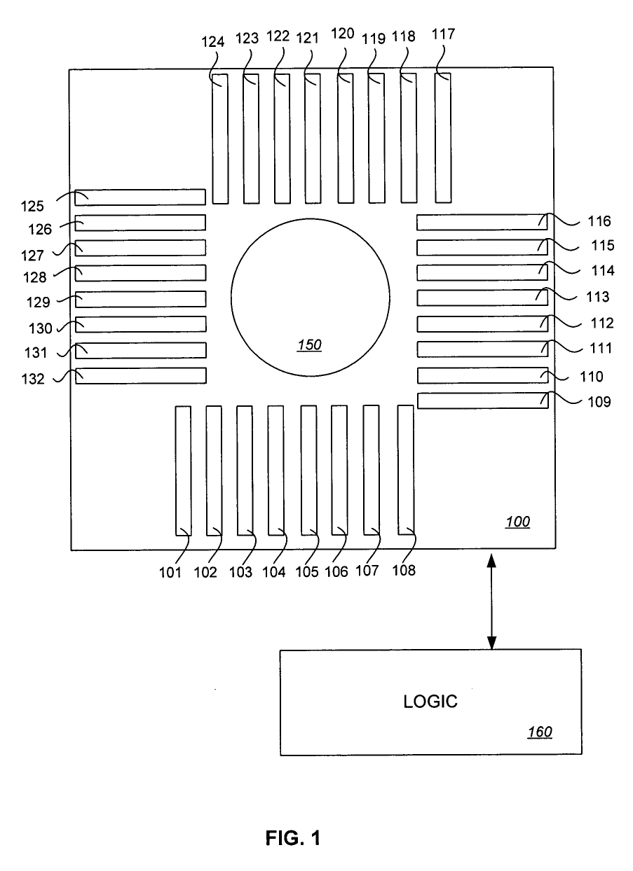

An exemplary embodiment of a system that may be used to calculate memory requirements for device testing is illustrated in FIG. 1. The system includes a tester 100 to test a device 150. By way of example, device 150 may be a system-on-a-chip (SOC). It should be appreciated that at times, tester 100 will not be coupled to a device 150.

Tester 150 includes a plurality of boards 101-132. Each board may include a plurality of pins (not shown) that may be used to drive inputs and receive outputs from device 150. In one embodiment, each pin may include its own memory to use during the testing of the device. The memory may be used to store pin specific vector information. In alternate embodiments, memory may not be included on each pin, but may instead be included for each board or other component of tester 100.

The system also includes logic 160 communicatively coupled to tester 100. Logic 160 may be part of a test operating system on a workstation coupled to tester 100 via a communication link, such as an optical link. In one embodiment, logic 160 may communicate with firmware (not shown) on tester 100 to send tests to device 150 and receive test results. In an alternate embodiment, logic 160 may be part of the firmware of tester 100.

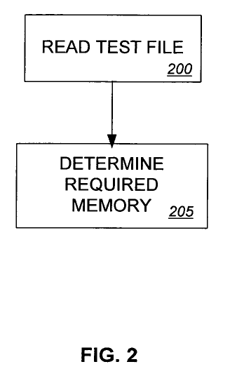

As shown in FIG. 2, logic 160 may be used to read 200 a test file containing one or more tests to be performed on device 150. Each of the tests may include a plurality of test vectors to be applied to device 150. Logic 160 may then determine 205 a required memory needed to execute the plurality of test vectors. By way of example, the number of test vectors for each test in the test file may be counted and the required memory may be determined to be equal to the number of test vectors required for the test with the highest number of test vectors.

The determination 205 may be performed before, during, or after, execution of the tests. If the determination is made before or during testing, a user may be notified of additional memory requirements or the memory may be dynamically increased as will be described below. In other embodiments, the maximum amount of memory may be made available to the tester and the memory calculation may be used to bill a customer after usage of the memory.

Logic 160 may determine 205 a required memory needed for each board of a tester to execute the test vectors for the board. In embodiments having a memory associated with each pin, a required memory needed for each board may be determined by determining the memory requirements for the pin with the highest memory usage. Alternately or additionally, logic 150 may determine 205 the required memory needed for each pin to execute the vectors for the pin.

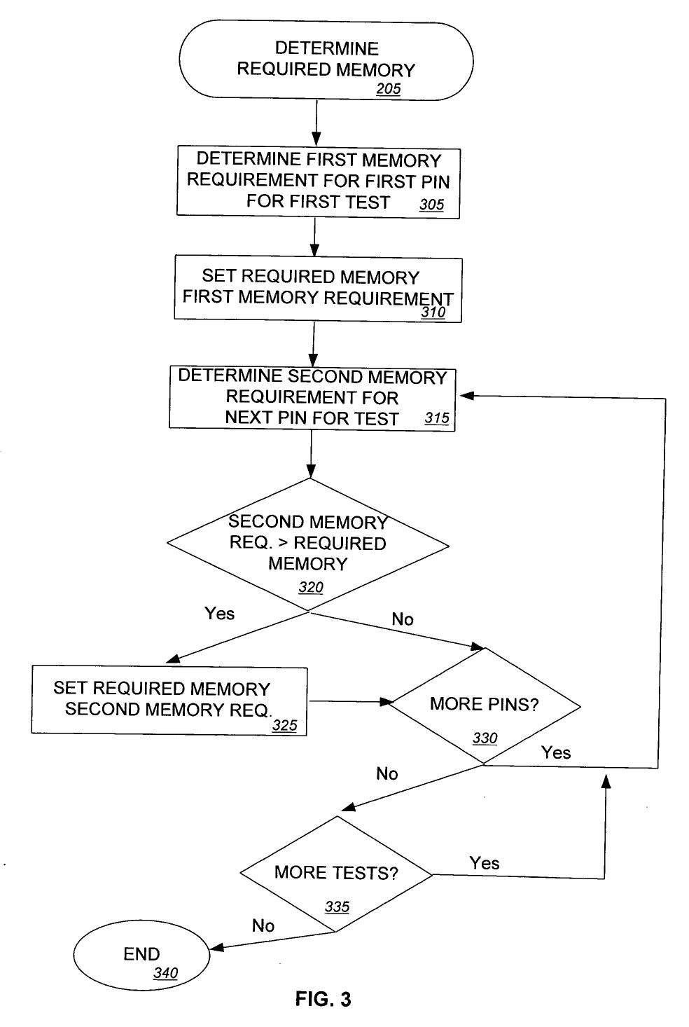

FIG. 3 illustrates an exemplary embodiment of a method for determining 205 a required memory. The method begins by determining 305 a first memory requirement for a first pin to execute the test vectors for a first test in the test file. By way of example, the first memory requirement may be determined 305 by counting the number of test vectors in the first test for the first pin. The required memory is then set 310 to be equal to the first memory requirement.

Another pin of the tester having test vectors in the first test is selected and a second memory requirement for the selected pin to execute the test vectors for the first test is determined 315. The second memory requirement may be determined 315 by counting the number of test vectors in the first test for the selected pin. If the second memory requirement exceeds the current value of the required memory 320, the required memory is set 325 equal to the second memory requirement.

After 325, or if the second memory requirement does not exceed the current value of the required memory 320, a determination is made as to whether there are more pins 330 having test vectors in the first test to process. If there are more pins, processing continues back at 315 for the next pin. Otherwise, a determination is made as to whether there are more tests in the test file 335.

If there are more tests, 315-330 are repeated for the next test for each pin having test vectors to execute for the test. After all the tests have been processed, the method ends 340. Thus, it should be appreciated that at the conclusion of the method the required memory is determined to be equal to the memory requirements for the test and pin combination with the highest memory requirements.

In alternate embodiments, the required memory may be determined in a manner different from that shown in FIG. 3. The determination 205 may depend upon how available memory is allocated in the tester. For example, in one embodiment, the memory available for a pin may depend on the board where the pin is located. Pins on one board may have the same amount of memory available as other pins on the same board, while the amount of memory available for pins may vary between boards. In this embodiment, a required memory may be calculated for each board by determining the memory requirements for the test and pin combination with the highest memory requirements for each board using a method similar to that described in FIG. 3. In a second embodiment, memory may be allocated on a per pin basis. In this embodiment, a required memory may be determined for each pin. Other exemplary embodiments, such as embodiments with one memory available for all the pins of a board, may use corresponding different calculations.

After the required memory needed to execute the tests in a test file has been determined 205, the required memory may be compared to an existing memory allotment. In some embodiments, the existing memory allotment may not be equal to a maximum amount of memory available in the tester 100 or components of tester 100. For business reasons, customers may only choose to purchase (and have available) a smaller amount of memory than the physical memory available in the tester. In other words, the available memory may be a “soft” restriction that can be dynamically changed. Therefore, if the required memory exceeds the existing memory allotment, logic 160 may increase the allotment of memory.

Depending upon the configuration of tester 100, and as previously described, the memory allotment may be increased for the entire tester 100, for one or more boards 101-132 of the tester, or for one or more pins on the tester. Alternately, logic 160 may notify a user of an amount of additional memory required to run the tests. Additional information, such as the test requiring the memory, may also be provided. Thus, it should be appreciated that by determining the memory requirements needed to execute the tests in a test file, failure of tests because of inadequate memory may be predicted or avoided.

While illustrative and presently preferred embodiments of the invention have been described in detail herein, it is to be understood that the inventive concepts may be otherwise variously embodied and employed, and that the appended claims are intended to be construed to include such variations, except as limited by the prior art.

1. A method comprising:
reading a test file including a plurality of test vectors to be applied to a device; and
determining a required memory needed to execute the plurality of test vectors.

2. The method of claim 1, wherein determining a required memory comprises determining a required memory needed for each of a plurality of boards of a tester to execute the test vectors for the board.

3. The method of claim 1, wherein determining a required memory comprises determining a required memory needed for each of a plurality of pins of a tester to execute the test vectors for the pin.

4. The method of claim 1, wherein determining a required memory comprises counting the number of test vectors for each test in the test file.

5. The method of claim 1, wherein determining a required memory comprises:
determining a first memory requirement needed for a first pin of a tester to execute the test vectors for a first test in the test file;
setting the required memory equal to the first memory requirement; and
for each additional pin of the tester,
determining a second memory requirement needed for the additional pin to execute the test vectors for the first test; and
if the second memory requirement is greater than the first memory requirement, setting the required memory equal to the second memory requirement.

6. The method of claim 5, further comprising for each additional test in the test file:
for each pin of the tester, determining a third memory requirement for the pin to execute the test vectors for the additional test; and setting the required memory equal to the third memory requirement if the third memory requirement is greater than the required memory.

7. The method of claim 1, further comprising if the required memory exceeds an existing memory allotment, increasing the allotment of memory.

8. The method of claim 1, further comprising if the required memory exceeds an existing memory allotment, notifying a user of an amount of additional memory required.

9. The method of claim 1, wherein the device comprises a system-on-a-chip (SOC).

10. A system comprising:
logic to read a test file including a plurality of test vectors and to determine a required memory needed to execute the plurality of test vectors; and
a tester, communicatively coupled to the logic, to apply the plurality of test vectors to a device.

11. The system of claim 10, wherein the tester includes a plurality of boards, and wherein the logic is to determine a required memory needed for each board of a tester to execute the test vectors for the board.

12. The system of claim 10, wherein the tester includes a plurality of boards, each board including a plurality of pins; and wherein the logic is to determine a required memory needed for each pin to execute the test vectors for the pin.

13. The system of claim 10, wherein the logic is to determine the required memory by counting the number of test vectors for each test in the test file.

14. The system of claim 10, further comprising a user interface to notify the user of an amount of additional memory required if the required memory exceeds an existing memory allotment.

15. The system of claim 10, wherein the tester comprises a system-on-a-chip (SOC) tester.
